(19) United States
(12) Patent Application Publication
(10) Pub. No.: US 2010/0263724 A1
(43) Pub. Date: Oct. 21, 2010

(54) SOLAR CELL MODULE

(76) Inventors: Kenichi Tazawa, Tokyo (JP); Kiichi Sakuma, Tokyo (JP)

Correspondence Address: Tomoko Nakajima;Cermak Nakajima LLP, 127 S. Peyton Street, Suite 210, Alexandria, VA, 22314, US

(21) Appl. No.: 12/741,925

(22) PCT Filed: Sep. 17, 2008
(86) PCT No.: PCT/JP2008/066775

§ 371 Date: May 7, 2010

(30) Foreign Application Priority Data
Nov. 9, 2007 (JP) 2007-291418

(51) Int. Cl. H01L 31/02

(52) U.S. Cl. 136/259

(57) ABSTRACT

A solar cell base body is attached to a frame smoothly and without being damaged. At the time of attaching the solar cell base body, a sealing material applied in a guide groove of the frame is prevented from protruding to the surface of the solar cell base body. Furthermore, the solar cell base body and the frame are stably fixed even when the solar cell module is at a high temperature and the sealing material is softened. The solar cell module includes the solar cell base body, the frame to be attached to the solar cell base body, and a spacer to be attached to the frame, wherein the frame is provided with at least a first base body supporting section for sandwiching the solar cell base body from the front surface, and a second base body supporting section for sandwiching the solar cell base body from the rear surface, a guide groove for inserting the solar cell base body is formed between the first base body supporting section and the second base body supporting section, and the spacers are attached to the second base body supporting section at predetermined intervals.

### TECHNICAL FIELD

The present invention relates to a solar cell module in which a spacer for guiding a solar cell base body is attached to a predetermined position of a frame into which the solar cell base body is inserted.

### BACKGROUND ART

Conventionally, the solar cell module is configured by enclosing the solar cell base body, which generates power by receiving solar light and the like by the frame made of aluminum and the like. The frame is attached so as to provide a structure for mounting to a support structure or to prevent humidity such as water from entering the solar cell base body from an end face thereof.

Also, in order to prevent more efficiently the humidity such as water from entering the solar cell base body from the end face thereof and to secure insulation properties between the frame and the solar cell base body, a sealing material such as butyl rubber seals between the frame and the solar cell base body.

Although it is necessary to insert the solar cell base body into the frame in an actual manufacturing process of such solar cell module, the solar cell base body cannot be smoothly inserted into the frame due to slight curvature and flexion of the solar cell base body and the frame, so that this takes time and effort.

Also, at the time of applying the sealing material in a guide groove of the frame and inserting the solar cell base body into the guide groove, there is a case in which the sealing material protrudes from the guide groove on a light receiving surface side of the solar cell base body, and in such a case, the protruded sealing material has to be removed each time and this deteriorates operation efficiency. Further, the sealing material also serves to bond the frame and the solar cell base body to each other, so that it is required that the solar cell base body is stably fixed to the frame even when the solar cell module is at a high temperature by receiving solar light and the like and the sealing material is softened.

Therefore, especially, in view of preventing the humidity from entering the solar cell base body and securing the insulation properties between the frame and the solar cell base body, the solar cell module including a solar cell and a support member for supporting the solar cell, wherein the supporting member has a metal portion, a spacer is included between the solar cell and the metal portion of the supporting member, and the spacer acts as a heat insulating material and maintains a shape thereof in an operating state of the solar cell is suggested (refer to Patent Document 1).

Patent Document 1: Japanese Patent Application Laid-Open No. 11-103086

### DISCLOSURE OF THE INVENTION

### Problem to be Solved by the Invention

According to the technique disclosed in Patent document 1, by using an insulating spacer, the insulation properties between the frame and the solar cell may be secured and an effect of preventing the sealing material from being softened to stabilize the frame and the solar cell may be obtained.

However, Patent document 1 suggests that a certain effect may be obtained by using a predetermined spacer in view of preventing the humidity from entering the solar cell base body and securing the insulation properties between the frame and the solar cell base body. But the spacer is attached to an entire frame and the spacer and the frame are formed into a C-shape corresponding to thickness of an end portion of the solar cell base body. Therefore, if there is distortion and flexion in the solar cell base body, the solar cell base body cannot be smoothly inserted into the frame. Also, since the frame or the spacer has the C-shape, there is a case in which the frame and the end face of the solar cell base body contact each other, thereby damaging the frame and the solar cell base body.

Also, at the time of attaching the solar cell base body to the frame, there is no escape for the pushed out sealing material and the solar cell base body is not closely attached to the frame, so that there is an issue that the sealing material protrudes to the surface of the solar cell base body. This is remarkable especially when the distortion and flexion of the solar cell base body are large, and the sealing material protrudes from a portion with the distortion and flexion, so that beauty in design is damaged and time and effort to remove the protruded sealing material is required.

Further, although the technique disclosed in Patent document 1 may prevent the sealing material from being softened to keep the stability of the frame and the solar cell base body by heat insulation properties of the spacer, since the spacer does not directly press the solar cell base body, it is not possible to keep the stability when the sealing material is softened.

Therefore, in order to solve the above issue, an object of the present invention is to smoothly attach the solar cell base body to the frame and to prevent the solar cell base body or the frame from being damaged at the time of attaching.

Also, another object of the present invention is to prevent the sealing material applied in the guide groove of the frame from protruding to the surface of the solar cell base body at the time of attaching the solar cell base body to the frame.

Further, still another object of the present invention is to provide the solar cell module in which the solar cell base body and the frame are stably fixed to each other even when the solar cell module is at a high temperature and the sealing material is softened.

### Means for Solving Problem

In order to achieve the above objects, a solar cell module according to the present invention is a solar cell module including a solar cell base body, a frame to be attached to the solar cell base body, and a spacer to be attached to the frame, wherein the frame includes at least a first base body supporting section for sandwiching the solar cell base body from a front surface and a second base body supporting section for sandwiching the solar cell base body from a rear surface, a guide groove for inserting the solar cell base body is formed between the first base body supporting section and the second base body supporting section, and the spacers are attached to the second base body supporting section at predetermined intervals.

Also, the guide groove may be formed so as to be narrower from an aperture plane toward a deep portion of the groove.

Also, the spacer may include an engaging section to be engaged with the second base body supporting section and a fixing section to abut the solar cell base body.

Also, a tilt surface for forming an aperture plane of the guide groove so as to be wider than a base end at an aperture of the guide groove is provided on the second base body supporting section, and the spacer may include a guide section corresponding to the tilt surface when being engaged with the second base body supporting section.

Also, a notch for displacing thickness of the fixing section according to insertion of the solar cell base body into the guide groove may be provided on a side of a surface abutting the solar cell base body of the fixing section.

Also, the frame may include a first locking section for locking motion of the spacer, and the spacer may include a second locking section for locking with the first locking section.

Also, a projected line may be provided on a position corresponding to the vicinity of an end face surface of the solar cell base body inserted into the guide groove on a bottom surface of the guide groove.

Also, the spacer may be formed of an insulating soft material.

Also, there is provided another solar cell module according to the present invention including a solar cell base body, a frame to be attached to the solar cell base body, and a spacer to be attached to the frame, wherein the frame includes at least a first base body supporting section for sandwiching the solar cell base body from a front surface and a second base body supporting section for sandwiching the solar cell base body from a rear surface, a guide groove for inserting the solar cell base body is formed between the first base body supporting section and the second base body supporting section so as to be narrower from an aperture plane toward a deep portion of the groove, a projected line is provided on a position corresponding to the vicinity of a surface of an end face of the solar cell base body inserted into the guide groove on a bottom surface of the guide groove, a tilt surface for forming the aperture plane of the guide groove so as to be wider than a base end at an aperture surface of the guide groove is provided on the second base body supporting section, the spacer is formed of an insulating soft material and includes an engaging section to be engaged with the second base body supporting section, a fixing section to abut the solar cell base body and a guide section corresponding to the tilt surface when being engaged with the second base body supporting section, and spacers are attached to the second base body supporting section at predetermined intervals.

### EFFECT OF THE INVENTION

According to the present invention, even if there is the curvature and flexion in the solar cell base body and the frame, the solar cell base body may be smoothly attached to the frame, and at the time of attaching, the solar cell base body or the frame may be prevented from being damaged.

Also, at the time of attaching the solar cell base body to the frame, it is possible to prevent the sealing material applied in the guide groove of the frame from protruding to the surface of the solar cell base body.

Further, even if the solar cell module is at a high temperature and the sealing material is softened, the stability of the solar cell base body and the frame may be secured.

### BRIEF DESCRIPTION OF THE DRAWINGS

FIG. 1 is an appearance front view illustrating a solar cell module according to a first embodiment of the present invention.

FIG. 2 is an appearance perspective view illustrating a frame of the solar cell module according to the present embodiment.

FIG. 3 is an appearance perspective view illustrating a spacer to be attached to the frame of the solar cell module according to the present embodiment.

FIG. 4 is an appearance perspective view illustrating the frame and the spacer attached to the frame in the solar cell module according to the present embodiment.

FIG. 5 is a cross-sectional view illustrating the frame and the spacer attached to the frame in the solar cell module according to the present embodiment.

FIG. 6 is a cross-sectional view illustrating a state in which a solar cell base body is attached to the frame to which the spacer is attached in the solar cell module according to the present embodiment.

FIG. 7 is a schematic diagram illustrating an attaching position of the spacer to be attached to the frame of the solar cell module according to the present embodiment.

FIG. 8 is an appearance perspective view illustrating the frame of the solar cell module according to a second embodiment of the present invention.

FIG. 9 is an appearance perspective view illustrating the spacer to be attached to the frame of the solar cell module according to the present embodiment.

FIG. 10 is an appearance perspective view illustrating the frame and the spacer attached to the frame in the solar cell module according to the present embodiment.

FIG. 11 is a cross-sectional view illustrating the frame and the spacer attached to the frame in the solar cell module according to the present embodiment.

FIG. 12 is a cross-sectional view illustrating a state in which the solar cell base body is attached to the frame to which the spacer is attached in the solar cell module according to the present embodiment.

### BEST MODE(S) FOR CARRYING OUT THE INVENTION

Hereinafter, a solar cell module according to a first embodiment of the present invention is described with reference to the drawings.

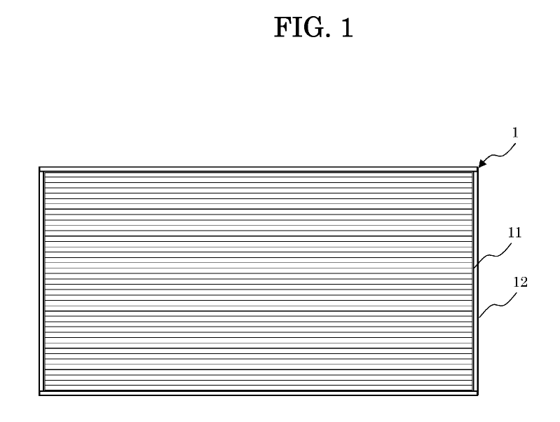

As illustrated in FIG. 1, a solar cell module 1 according to the present embodiment includes of a solar cell base body 11 and a frame 12, and a spacer 2 to be described below is attached to a predetermined position of the frame 12.

The solar cell base body 11 includes a substrate glass, a solar cell device stacked on the substrate glass, and a cover glass to be attached to a light receiving surface of the solar cell device, and a sealant such as EVA resin is applied between the substrate glass and the cover glass and they are integrated with each another. Also, a rear surface material such as a weather-resistant film is attached to a rear surface of the substrate glass.

The solar cell device receives solar light and the like, and by this, the solar cell module 1 may generate power and output electricity to outside by means of a predetermined terminal and the like.

The frame 12 encloses an end face of the solar cell base body 11 to hold the solar cell base body 11 while preventing humidity from entering the solar cell base body 11 from the end face thereof, and is made of aluminum and the like.

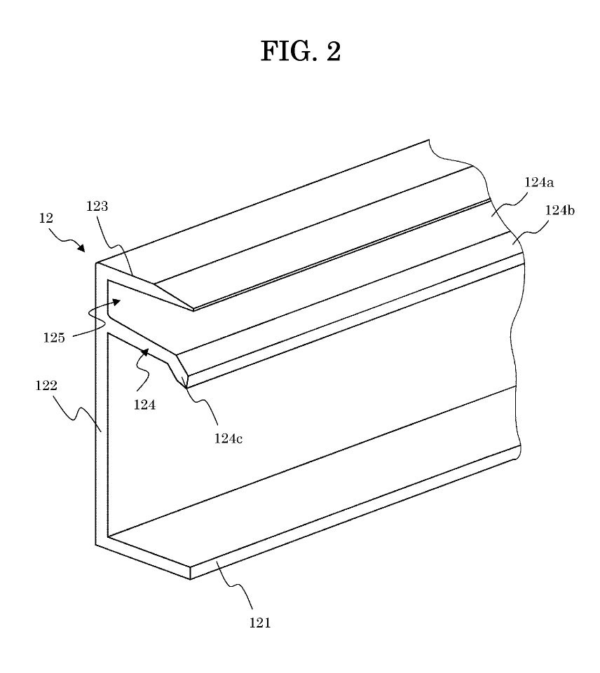

The frame 12 includes a bottom section 121 grounded to a mounting surface for mounting the solar cell module 1 such as a roof and a support structure, a supporting column section 122 vertically extending from the bottom section 121, and base body supporting sections 123 and 124 extending from the supporting column section 122, as illustrated in FIG. 2.

A guide groove 125 for inserting the solar cell base body 11 is formed between the base body supporting sections 123 and 124, and the solar cell base body 11 inserted from an aperture plane of the guide groove 125 is sandwiched between the base body supporting sections 123 and 124.

Herein, the base body supporting section 123 is configured to extend at a right angle relative to the supporting column section 122 to be parallel to the bottom section 121.

Also, the base body supporting section 124 is configured to extend from the supporting column section 122 slightly obliquely downward relative to the supporting column section 122 such that the guide groove 125 becomes wider in small increments from a bottom section toward an aperture of the groove.

Also, the base body supporting section 124 is bent at a tip end thereof slightly obliquely downward relative to a base end 124a of the base body supporting section 124 to compose a tilt section 124b such that the aperture plane of the guide groove 125 becomes wider, and further, a tip end of the tilt section 124b composes an engaging section 124c for engaging with a spacer 2.

Width of the bottom section of the guide groove 125 thus configured is slightly larger than thickness of the solar cell base body 11 and the aperture plane becomes wider in small increments in a direction toward the aperture as described above, so that the solar cell base body 11 is easily inserted into the guide groove 125.

The spacer 2 serves as a guide at the time of attaching the solar cell base body 11 to the frame 12 and stably fixes the frame 11 and the solar cell base body 12 to each other.

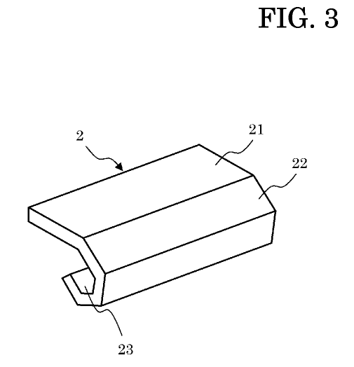

The spacer 2 has a shape in which a tilt surface is provided by bending of a rectangular thin plate and an edge of one side on an extension of the tilt surface is folded back, as illustrated in FIG. 3. Then, a flat plate section composes a fixing section 21, which abuts the solar cell base body 11 to fix the solar cell base body 11 to the frame 12, the tilt surface composes a guide section 22, which guides the solar cell base body 11 from the aperture plane into the guide groove 125 and a folded-back section composes an engaging section 23 for engaging with the frame 12.

Meanwhile, as a material of the spacer 2, a soft material such as resin may be used in addition to a hard material such as plastic and rubber, and an insulating material is used. In the present embodiment, it is described based on a case in which an insulating soft material is used.

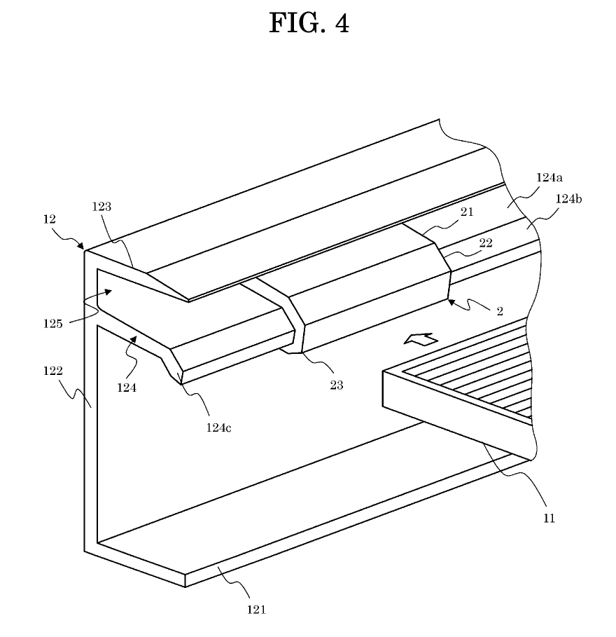

Subsequently, a process of attaching the spacer 2 to the frame 12 and attach the solar cell base body 11 to the frame 12 is described with reference to FIGS. 4 to 6.

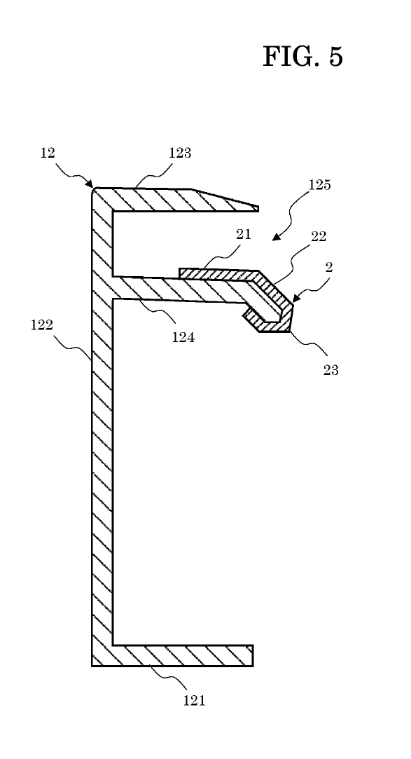

First, as illustrated in FIGS. 4 and 5, the engaging section 23 of the spacer 2 is engaged with the engaging section 124c of the frame 12 to attach the spacer 2 to the frame 12.

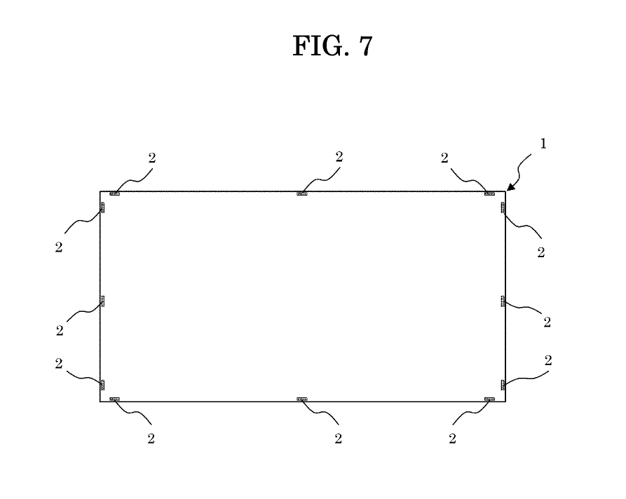

Herein, the spacer 2 is attached in the vicinity of both ends and a central portion of longitudinal frames 12, and is also attached in the vicinity of both ends and a central portion of transverse frames 12 as illustrated in FIG. 7, so that a total of 12 spacers 2 are attached at predetermined intervals.

Meanwhile, although a total of 12 spacers 2 are attached to the frames 12 in the present embodiment, the number is not limited to this in the embodiment of the present invention, and the spacers 2 may be attached at predetermined intervals and the attaching number is not limited.

Also, although the interval between the attached spacers 2 is not especially limited, they are attached at an interval from 200 mm to 800 mm, for example.

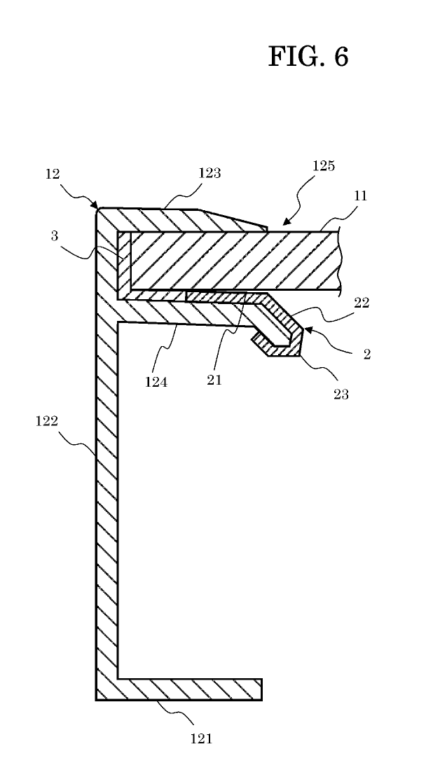

After attaching the spacer 2 to the frame 12, at the time of attaching the solar cell base body 11 to the frame 12, as illustrated in FIGS. 4 and 6, a sealing material 3 such as butyl rubber is applied in the guide groove 125 of the frame 12 and the solar cell base body 11 is inserted from the aperture plane of the guide groove 125. Meanwhile, the sealing material 3 prevents the humidity from entering the solar cell base body 11 from the end face thereof and secures insulation properties between the solar cell base body 11 and the frame 12.

At that time, by applying the end face of the solar cell base body 11 to the guide section 22 and by inserting the solar cell base body 11 while allowing the same to slidingly contact the fixing section 21, it is possible to prevent the frame 12, especially an end face of the base body supporting section 123, and the end face of the solar cell base body 11 from colliding with each other, thereby damaging the frame 12 or the solar cell base body 11.

When inserting the solar cell base body 11 into the guide groove 125, the aperture plane of the guide groove 125 becomes narrower toward an inner side of the groove. Therefore, when the solar cell base body 11 is inserted to a certain degree, this is subjected to drag force from the fixing section 21 of the spacer 2 and abuts a lower surface of the base body supporting section 123 to be sandwiched therebetween, and is fixed to the frame 12.

Herein, although the sealing material 3 applied deep in the guide groove 125 is pressed by the solar cell base body 11 and tends to protrude from the guide groove 125, since the solar cell base body 11 is closely attached to the lower surface of the base body supporting section 123 by being subjected to the drag force from the spacer 2, this does not protrude from between the solar cell base body 11 and the base body supporting section 123 to a surface of the solar cell base body 11 and only protrudes from a side of the spacer 2 to a rear surface of the solar cell base body 11.

According to this, the solar cell base body 11 may be easily attached to the frame 12 and beauty in design may be kept without the sealing material 3 protruding to the surface of the solar cell base body 11.

Next, a second embodiment of the present invention is described.

The solar cell module according to the present embodiment includes a solar cell base body 41 and a frame 42, and a spacer 5 to be described below is attached to a prescribed position of the frame 42.

Meanwhile, an appearance of the solar cell module is similar to that of the solar cell module 1 illustrated in FIG. 1. Also, a configuration of the solar cell base body 41 is similar to that of the solar cell base body 11.

The frame 42, as the frame 12, encloses the end face of the solar cell base body 41 to hold the same and prevents the humidity from entering the solar cell base body 41 from the end face thereof, and is made of aluminum and the like.

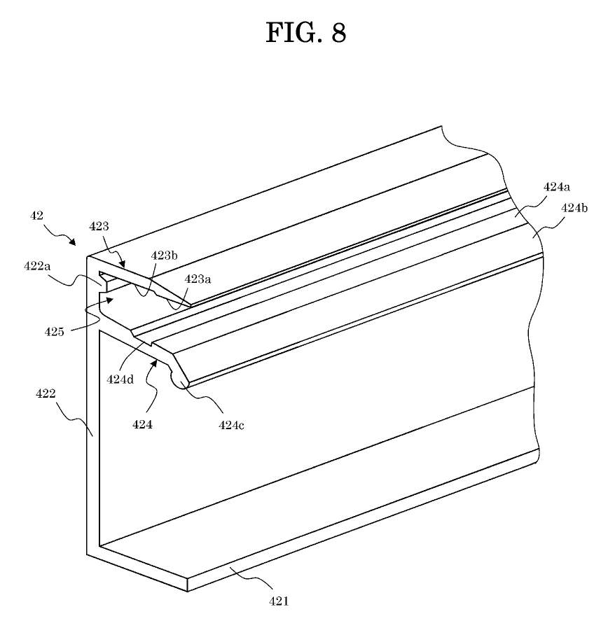

The frame 42 includes a bottom section 421 grounded to the mounting surface for mounting the solar cell module such as the roof and the support structure, a supporting column section 422 extending from the bottom section 421 at a right angle, and base body supporting sections 423 and 424 extending from the supporting column section 422, as illustrated in FIG. 8.

The supporting column section 422 is provided with a projected line 422a near the base body supporting section 423 at a position deep in the guide groove 425 formed of the base body supporting sections 423 and 424. With the projected line 422a, under the use of the solar cell module, even when the solar cell base body 41 pushes the sealing material 3 applied in the guide groove 425 out and contacts the frame 42, only the vicinity of the cover glass portion of the solar cell base body 41 abuts the projected line 422a, so that it is possible to prevent the rear surface material attached to the rear surface of the solar cell base body 41 from contacting the frame 42. Since the rear surface material generally has aluminum foil enclosed therein, a defect such as lowering of power generation efficiency might occur when this contacts the frame 42 made of metal, so that such defect may be prevented from occurring with the projected line 422a.

A guide groove 425 for inserting the solar cell base body 41 is formed between the base body supporting sections 423 and 424 and the solar cell base body 41 inserted from the aperture plane of the guide groove 425 is sandwiched between the base body supporting sections 423 and 424.

Herein, as in the first embodiment, the base body supporting section 423 is configured to extend at a right angle relative to the supporting column section 422 so as to be parallel to the bottom section 421.

Also, the base body supporting section 424 is configured to extend from the supporting column section 422 slightly obliquely downward relative to the supporting column section 422 such that the guide groove 425 becomes wider in small increments from the bottom section toward the aperture of the groove.

The base body supporting section 423 is provided with an abutting section 423a and a reservoir section 423b on a guide groove 425 side thereof.

The abutting section 423a is configured as a smooth surface, which abuts the solar cell base body 41 at a tip end of the base body supporting section 423.

The reservoir section 423b is a groove-like recess slightly depressed from the abutting section 423a. When the sealing material 3 applied deep in the guide groove 425 is pushed out by the solar cell base body 41, the pushed out sealing material 3 is reserved in the reservoir section 423b, so that it is possible to prevent the sealing material 3 from being pushed out to the surface of the solar cell base body 41.

The base body supporting section 424 is bent slightly obliquely downward relative to a base end 424a of the base body supporting section 424 to compose a tilt section 424b such that the aperture plane of the guide groove 425 becomes wide at the tip end thereof, and further, a tip end of the tilt section 424b composes an engaging section 424c for engaging with the spacer 5. Meanwhile, unlike the engaging section 124c in the first embodiment, a rear surface of the engaging section 424c is swollen to form a semicircle in cross section.

Width of the bottom section of the guide groove 425 thus configured is slightly larger than thickness of the solar cell base body 41, and the aperture plane thereof becomes wider in small increments in a direction toward the aperture as described above, so that the solar cell base body 41 is easily inserted into the guide groove 425. Also, the rear surface of the engaging section 424 is swollen to form the semicircle in cross section. Therefore, when the spacer 5 is engaged with the engaging section 424, a hanging portion becomes larger and the spacer 5 is hardly detached.

Also, a locking groove 424d is provided on a guide groove 425 side of the base body supporting section 424 for preventing the spacer 5 from being detached in association with motion of the solar cell base body 41 and for stably fixing the solar cell base body 41 to the frame 42. A corner of the locking groove 424d on an aperture side of the guide groove 425 is formed into a right angle and that on a side deep in the guide groove 425 is formed into an obtuse angle.

The spacer 5 serves as a guide at the time of attaching the solar cell base body 41 to the frame 42 and stably fixes the frame 42 and the solar cell base body 41.

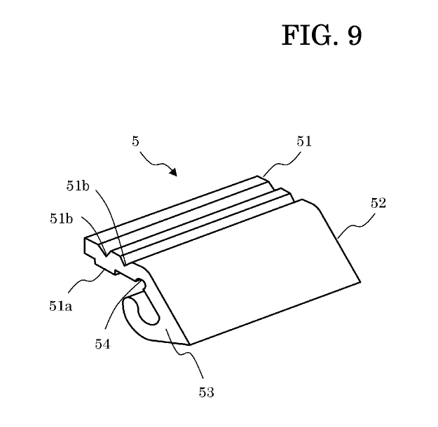

The spacer 5 has the shape in which the tilt surface is provided by bending of the rectangular thin plate and the edge of one side on the extension of the tilt surface is folded back, as illustrated in FIG. 9. Then, the flat plate section composes a fixing section 51, which abuts the solar cell base body 41 to fix the solar cell base body 41 to the frame 42, the tilt surface composes a guide section 52 for guiding the solar cell base body 41 from the aperture plane into the guide groove 425 and the folded-back section composes an engaging section 53 for engaging with the frame 42.

Meanwhile, as the material of the spacer 5, as in the first embodiment, the soft material such as resin may be used in addition to the hard material such as plastic and rubber, and the insulating material or a material having a predetermined resistance value is used. In the present embodiment, it is described based on a case in which the insulating soft material is used.

In the fixing section 51, a locking section 51a is provided on a rear surface side, which abuts the base body supporting section 424, and a V-shaped groove 51b is provided on a front surface side.

The locking section 51a has a corner formed into a right angle, and this is locked with the locking groove 424d of the frame 42 to prevent the spacer 5 from disengaging from the frame 42 and stably fixes the solar cell base body 41 to the frame 42.

The V-shaped groove 51b is provided so as to be orthogonal to a direction of insertion of the solar cell base body 41 inserted into the guide groove 425. A protrusion of the V-shaped groove 51b is pressed and groove width becomes wider such that the V-shaped groove becomes wider or the groove width thereof becomes narrower such that the V-shaped groove becomes narrower in association with the motion of the solar cell base body 41, which abuts the fixing section 51, thereby displacing the thickness of the fixing section 51. According to this, even when the solar cell base body 41 moves in the guide groove 425 in some measures, the fixing section 51 may be pressed against the solar cell base body 41, thereby stably fixing the solar cell base body 41 and the frame 42 to each other. Meanwhile, a shape of the V-shaped groove 51b is not limited to the V-shape and this may be a U-shape and the like.

The guide section 52 has a shape corresponding to the tilt section 424b of the base body supporting section 424 and guides the solar cell base body 41 into the guide groove 425 at the time of inserting the solar cell base body 41 into the guide groove 425.

The engaging section 53 is shaped by being folded back such that an inner peripheral surface thereof forms a substantial semicircle and may be engaged with the engaging section 424c of the frame 42.

Also, on the engaging section 53, a buffer groove 54 formed into a substantially semicircular shape in cross section with a small diameter is provided on a position, which abuts a portion of the base body supporting section 424 bent so as to form the tilt section 424b, when attaching the spacer 5 to the base body supporting section 424, that is to say, on a boundary portion of the fixing section 51 and the guide section 52 of a rear surface side, which abuts the base body supporting section 424. With the buffer groove 54, force received from the bent portion of the base body supporting section 424, which is easily subjected to the force than other portions, may be allowed to escape when attaching the spacer 5 to the base body supporting section 424, and burden to the spacer 5 may be reduced.

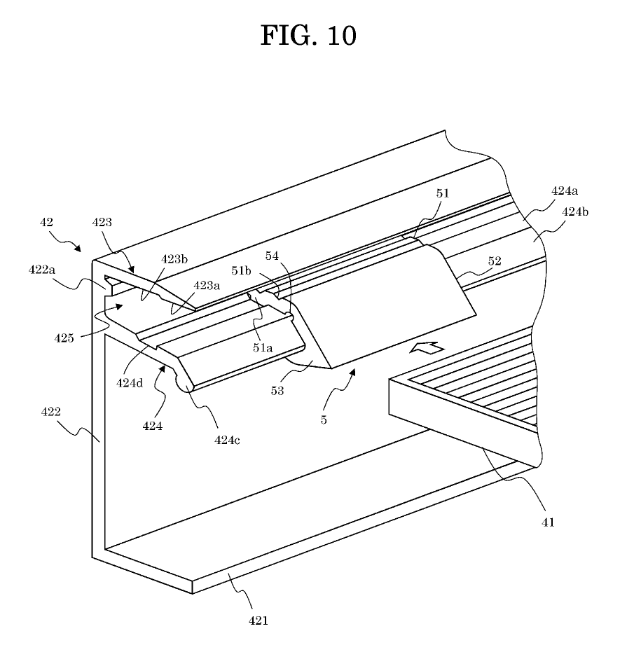

Subsequently, a process of attaching the spacer 5 to the frame 42 and attaching the solar cell base body 41 to the frame 42 is described with reference to FIGS. 10 to 12.

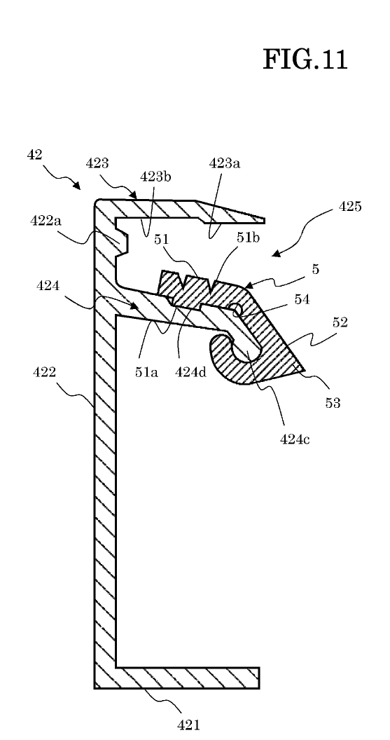

First, as illustrated in FIGS. 10 and 11, the engaging section 53 of the spacer 5 is engaged with the engaging section 424c of the frame 42 to attach the spacer 5 to the frame 42.

Herein, as in the first embodiment, the spacer 5 is attached in the vicinity of both ends and a central portion of longitudinal frames 4, and is also attached in the vicinity of both ends and a central portion of transverse frames 42, so that a total of 12 spacers 5 are attached at predetermined intervals.

Meanwhile, although a total of 10 spacers 5 are attached to the frame 42 in the present embodiment, the number is not limited to this in the embodiment of the present invention, and the spacers 5 may be attached at predetermined intervals and the attaching number is not limited.

Also, although the interval between the attached spacers 5 is not especially limited, they are attached at an interval of 200 mm to 800 mm as an example.

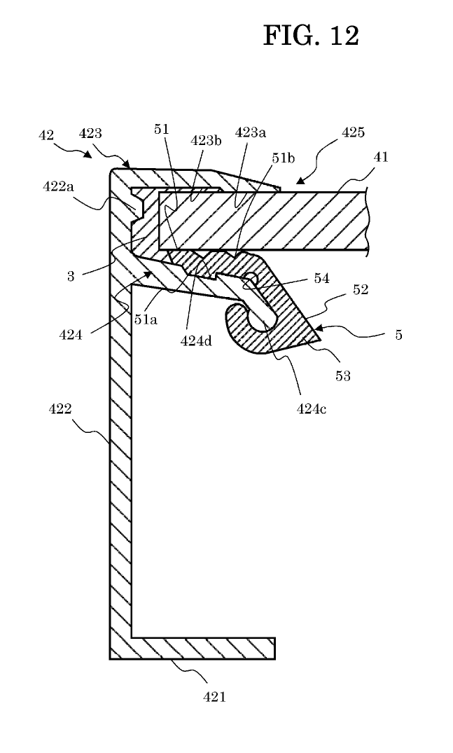

After attaching the spacer 5 to the frame 42, as illustrated in FIGS. 10 and 12, the sealing material 3 such as butyl rubber is applied in the guide groove 425 of the frame 42 and the solar cell base body 11 is inserted from the aperture plane of the guide groove 425. Meanwhile, the sealing material 3 prevents the humidity from entering the solar cell base body 41 from the end face thereof and secures the insulation properties between the solar cell base body 41 and the frame 42.

At that time, by applying the end face of the solar cell base body 41 to the guide section 52 and by inserting the solar cell base body 41 while allowing the same to perform sliding contact the fixing section 51, it is possible to prevent the frame 42, especially an end face of the base body supporting section 423, and the end face of the solar cell base body 41 from colliding with each other, thereby damaging the frame 42 or the solar cell base body 41.

Meanwhile, the deep side corner of the locking groove 424d is formed into an obtuse angle, so that at the time of inserting the solar cell base body 41 into the guide groove 425, even when the spacer 5 is subjected to force in the direction of insertion from the solar cell base body 41, the locking section 51a of the spacer 5 is displaced by an amount of the obtuse angle of the locking groove 424d to absorb the force applied to the locking section 51a.

When inserting the solar cell base body 41 into the guide groove 425, the aperture plane of the guide groove 425 becomes narrower toward the inner side of the groove. When the solar cell base body 41 is inserted to a certain degree, this is subjected to the drag force from the fixing section 51 of the spacer 5 and abuts the lower surface of the base body supporting section 423 to be sandwiched therebetween, and is fixed to the frame 42.

Herein, the sealing material 3 applied deep in the guide groove 425 is pressed by the solar cell base body 41 and tends to protrude from the guide groove 425, this is reserved in the reservoir section 423b and does not protrude to the surface of the solar cell base body 41. Also, since the solar cell base body 41 is subjected to the drag force from the spacer 5 and is pressed against to the lower surface of the base body supporting section 423, this does not protrude from between the solar cell base body 41 and the base body supporting section 423 to the surface of the solar cell base body 41 and only protrudes from the side of the spacer 5 to the rear surface of the solar cell base body 41.

According to this, the solar cell base body 41 may be easily attached to the frame 42 and beauty in design may be kept without the sealing material 3 protruding to the surface of the solar cell base body 41. Further, the solar cell base body 41 may be stably fixed to the frame 42.

### DESCRIPTION OF REFERENCE NUMERALS

1 solar cell module
11 solar cell base body
12 frame
121 bottom section
122 supporting column section
123 base body supporting section
124 base body supporting section
124a base end
124b tilt section
124c engaging section
125 guide groove
2 spacer
21 fixing section
22 guide section
23 engaging section
3 sealing material
41 solar cell base body
42 frame
421 bottom section
422 support column section
422a projected line
423 base body supporting section
423a abutting section
423b reservoir section
424 base body supporting section
424a base end
424b tilt section
424c engaging section
424d locking groove
425 guide groove
5 spacer
51 fixing section
51a locking section
51b V-shaped groove
52 guide section
53 engaging section
54 buffer groove

1. A solar cell module, comprising:
a solar cell base body;
a frame to be attached to the solar cell base body; and
a spacer to be attached to the frame, wherein
the frame includes at least a first base body supporting section for sandwiching the solar cell base body from a front surface and a second base body supporting section for sandwiching the solar cell base body from a rear surface,
a guide groove for inserting the solar cell base body is formed between the first base body supporting section and the second base body supporting section, and
spacers are attached to the second base body supporting section at predetermined intervals.

2. The solar cell module according to claim 1, wherein
the guide groove is formed so as to be narrower from an aperture plane toward a deep portion of the groove.

3. The solar cell module according to claim 1, wherein
the spacer includes an engaging section to be engaged with the second base body supporting section and a fixing section to abut the solar cell base body.

4. The solar cell module according to claim 1, wherein
a tilt surface for forming an aperture plane of the guide groove so as to be wider than a base end at an aperture of the guide groove is provided on the second base body supporting section, and
the spacer includes a guide section corresponding to the tilt surface when being engaged with the second base body supporting section.

5. The solar cell module according to claim 3, wherein
a notch for displacing thickness of the fixing section according to insertion of the solar cell base body into the guide groove is provided on a side of a surface abutting the solar cell base body of the fixing section.

6. The solar cell module according to claim 1, wherein
the frame includes a first locking section for locking motion of the spacer, and
the spacer includes a second locking section for locking with the first locking section.

7. The solar cell module according to claim 1, wherein
a projected line is provided on a position corresponding to the vicinity of a surface of an end face of the solar cell base body inserted into the guide groove on a bottom surface of the guide groove.

8. The solar cell module according to claim 1, wherein
the spacer is formed of an insulating soft material.

9. A solar cell module, comprising:
a solar cell base body;
a frame to be attached to the solar cell base body; and
a spacer to be attached to the frame, wherein
the frame includes at least a first base body supporting section for sandwiching the solar cell base body from a front surface and a second base body supporting section for sandwiching the solar cell base body from a rear surface,
a guide groove for inserting the solar cell base body is formed between the first base body supporting section and the second base body supporting section so as to be narrower from an aperture plane toward a deep portion of the groove,
a projected line is provided on a position corresponding to the vicinity of a surface of an end face of the solar cell base body inserted into the guide groove on a bottom surface of the guide groove,
a tilt surface for forming the aperture plane of the guide groove so as to be wider than a base end at an aperture of the guide groove is provided on the second base body supporting section,
the spacer is formed of an insulating soft material and includes an engaging section to be engaged with the second base body supporting section, a fixing section to abut the solar cell base body and a guide section corresponding to the tilt surface when being engaged with the second base body supporting section, and
spacers are attached to the second base body supporting section at predetermined intervals.
